(19) United States
(12) Patent Application Publication
(10) Pub. No.: US 2014/0124252 A1
(43) Pub. Date: May 8, 2014

(54) TOUCH SENSOR AND METHOD OF MANUFACTURING THE SAME

(71) Applicant: SAMSUNG ELECTRO-MECHANICS CO., LTD., Suwon (KR)

(72) Inventors: Jae Chan Park, Suwon (KR); Ho Joon Park, Suwon (KR)

(73) Assignee: Samsung Electro-Mechanics Co., Ltd., Suwon (KR)

(21) Appl. No.: 13/831,808

(22) Filed: Mar. 15, 2013

(30) Foreign Application Priority Data
Nov. 6, 2012 (KR) 10-2012-0124911

(51) Int. Cl. H05K 1/03; H05K 3/10

(52) U.S. Cl. CPC H05K 1/0306; H05K 3/10
USPC 174/257; 174/250; 174/258; 29/852

(57) ABSTRACT

Disclosed herein are a touch sensor and a method of manufacturing the same. The touch sensor according to the preferred embodiment of the present invention includes; a transparent substrate; a first electrode formed on one surface of the transparent substrate; a first insulating layer formed on one surface of the first electrode and formed with a through-hole; and a second electrode formed on one portion of one surface of the insulating layer, wherein the first electrode is extendedly formed to the other portion of one surface of the insulating layer through the through-hole.

### CROSS REFERENCE TO RELATED APPLICATION

This application claims the benefit of Korean Patent Application No. 10-2012-0124911, filed on Nov. 6, 2012, entitled “Touch Sensor and Method of Manufacturing the Same,” which is hereby incorporated by reference in its entirety into this application.

### BACKGROUND OF THE INVENTION

1. Technical Field

The present invention relates to a touch sensor and a method of manufacturing the same.

2. Description of the Related Art

Recently, a touch screen panel used for a smart phone and a tablet PC is suddenly shifted from an existing resistive type to a capacitive type.

As a type that has been widely applied to a capacitive type touch sensor, a GFF, G1, or G2 type glass sensor is mainly used.

Here, the GFF type touch sensor is configured of two sheets of PET films in which ITO is deposited/patterned under a window glass.

Further, the G1 or G2 type touch sensor senses x and y coordinate locations on a glass surface while measuring a value of a capacitor suddenly changed when a conductor is touched in a state in which ITO electrodes are formed on one sheet or two sheets of window glasses in a single layer or a double layer so that two electrodes of an x axis (touch electrode) and a y axis (sensing electrode) are electrically balanced with each other based on the value of the capacitor and generates electrical signals according to a touch on the locations to execute programs, thereby sensing the touch.

However, as described in Korean Patent Laid-Open Publication No. 2012-0044268, when the touch electrode and the sensing electrode are formed on a single layer, an area in which the ITO electrode may be formed is limited and resistance is increased due to the narrow area, such that touch sensitivity may be degraded.

### PRIOR ART DOCUMENT

(Patent Document 1) Korean Patent Laid-Open Publication No. 2012-0044268

### SUMMARY OF THE INVENTION

The present invention has been made in an effort to provide a touch sensor capable of reducing a resistance of an electrode and a method of manufacturing the same.

Further, the present invention has been made in an effort to provide a touch sensor capable of easily blocking noise generated from a display and a method of manufacturing the same.

According to a preferred embodiment of the present invention, there is provided a touch sensor, including: a transparent substrate; a first electrode formed on one surface of the transparent substrate; a first insulating layer formed on one surface of the first electrode and formed with a through-hole; and a second electrode formed on one surface of the first insulating layer, wherein the first electrode is extendedly formed to one surface of the first insulating layer through the through-hole.

The transparent substrate may be formed of a film or glass.

The first insulating layer may be formed of silicon dioxide (SiO₂).

The first electrode and the second electrode may be formed of indium tin oxide (ITO).

The first electrode and the second electrode may have patterns formed on one surface of the first insulating layer to sense a touch.

The first electrode may have a pattern formed on one surface of the first insulating layer and the second electrode may have a pattern formed on one surface of the first insulating layer and corresponding to the pattern of the first electrode.

The first electrode may have a plurality of circular or quadrangular patterns formed on one surface of the first insulating layer and the second electrode may have patterns formed on one surface of the first insulating layer and corresponding to the patterns of the first electrode while being spaced apart from an edge of the first electrode at a predetermined distance.

The touch sensor may further include: a first electrode wiring and a second electrode wiring each formed at edges of the first electrode and the second electrode.

According to another preferred embodiment of the present invention, there is provided a method of manufacturing a touch sensor including: primarily forming a first electrode on one to surface of a transparent substrate; forming a first insulating layer formed with a through-hole and formed on one surface of the first electrode; and secondarily forming a second electrode and the first electrode extending through the through-hole on one surface of the first insulating layer.

The transparent substrate may be formed of a film or glass.

In the forming of the first insulating layer, the first insulating layer may be formed of a silicon dioxide (SiO₂) material.

The method of manufacturing a touch sensor may further include: after the primarily forming of the electrode, forming a first electrode wiring at an edge of the first electrode.

The method of manufacturing a touch sensor may further include: after the secondarily forming of the electrode, forming a second electrode wiring at an edge of the second electrode.

The first electrode and the second electrode may be formed of indium tin oxide (ITO).

In the primarily forming of the electrode and the secondarily forming of the electrode, the first electrode and the second electrode may be formed by deposition.

In the secondarily forming of the electrode, the first electrode may have a pattern formed on one surface of the first insulating layer, and the second electrode may have a pattern corresponding to the pattern of the first electrode.

In the secondarily forming of the electrode, the first electrode may have a plurality of circular or quadrangular patterns formed on one surface of the first insulating layer, and the second electrode may have patterns formed on one surface of the first insulating layer and corresponding to the patterns of the first electrode while being spaced apart from an edge of the first electrode at a predetermined distance.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a side cross-sectional view illustrating a touch sensor according to a preferred embodiment of the present invention;

FIG. 2 is a plan view illustrating an example of an electrode pattern in the touch sensor according to the preferred embodiment of the present invention;

FIG. 3 is a plan view illustrating another example of the electrode pattern in the touch sensor according to the preferred embodiment of the present invention;

FIG. 4 is a flow chart illustrating a method of manufacturing a touch sensor according to a preferred embodiment of the present invention; and

FIGS. 5 to 10 are conceptual diagrams illustrating a method of manufacturing a touch sensor according to the preferred embodiment of the present invention in a process order.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

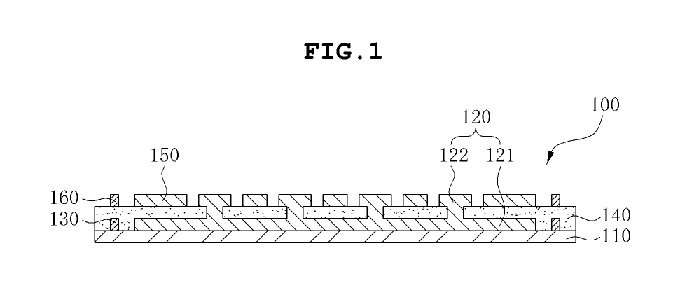

FIG. 1 is a side cross-sectional view illustrating a touch sensor according to a preferred embodiment of the present invention.

Referring to FIG. 1, a touch sensor 100 according to a preferred embodiment of the present invention may include a transparent substrate 110, a first electrode 120, a first insulating layer 140, and a second electrode 150.

Hereinafter, the touch sensor 100 according to the preferred embodiment of the present invention will be described in more detail with reference to FIG. 1.

Referring to FIG. 1, the transparent substrate 110 provides a substrate part on which an electrode is formed and may be, for example, glass or tempered glass, but a material of the transparent substrate 110 according to the preferred embodiment of the present invention is not necessarily formed of a glass material and therefore, as another example, the transparent substrate 110 may be formed of a film. Here, the transparent substrate 110 may be formed in a rectangular plate shape having a predetermined thickness, but the shape of the transparent substrate 110 according to the preferred embodiment of the present invention is not limited thereto.

In this case, the film may be formed of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), and the like, but are not necessarily limited thereto.

One portion of the first electrode 120 is formed on one surface of the transparent substrate 110. Here, the first electrode 120 may be formed of indium-tin oxide (ITO). Further, one portion 121 of the first electrode 120 formed on one surface of the transparent substrate 110 may be formed in a rectangular plate shape, but the preferred embodiment of the present invention is not limited thereto.

The first insulating layer 140 is formed on one surface of the first electrode 120. In this case, the first insulating layer 140 is provided with a plurality of through-holes 141 penetrating through both surfaces thereof. Here, a flat cross section of the through-hole 141 may have, for example, a circular or quadrangular shape, but the present invention is not limited thereto.

The first insulating layer 140 protects one portion 121 of the first electrode 120 and serves to provide a region in which the other portion 122 of the first electrode 120 and the second electrode 150 are formed. Here, the first insulating layer 140 may be formed of epoxy or acrylic based resin, a SiOx thin film, a SiNx thin film, and the like, by printing, chemical vapor deposition (CVD), sputtering, and the like. In this case, the first insulating layer 140 may be formed of, for example, silicon dioxide (SiO₂), but a material of the first insulating layer 140 according to the preferred embodiment of the present invention is not limited thereto.

The second electrode 150 is formed on one portion of one surface of the first insulating layer 140. Here, the second electrode 150 may be formed of indium-tin oxide (ITO).

Further, the second electrode 150 is formed at an outside of the through-hole 141 that is formed on the first insulating layer 140 and is formed on one surface of the first insulating layer 140 except for the through-hole 141 and a circumference of the through-hole 141. In this case, the through-hole 141 and the circumference of the through-hole 141 are extendedly formed with the first electrode 120.

Therefore, one portion of one surface of the first insulating layer 140 may be formed with the second electrode 150 and the other portion thereof may be formed with the other portion 122 of the first electrode 120.

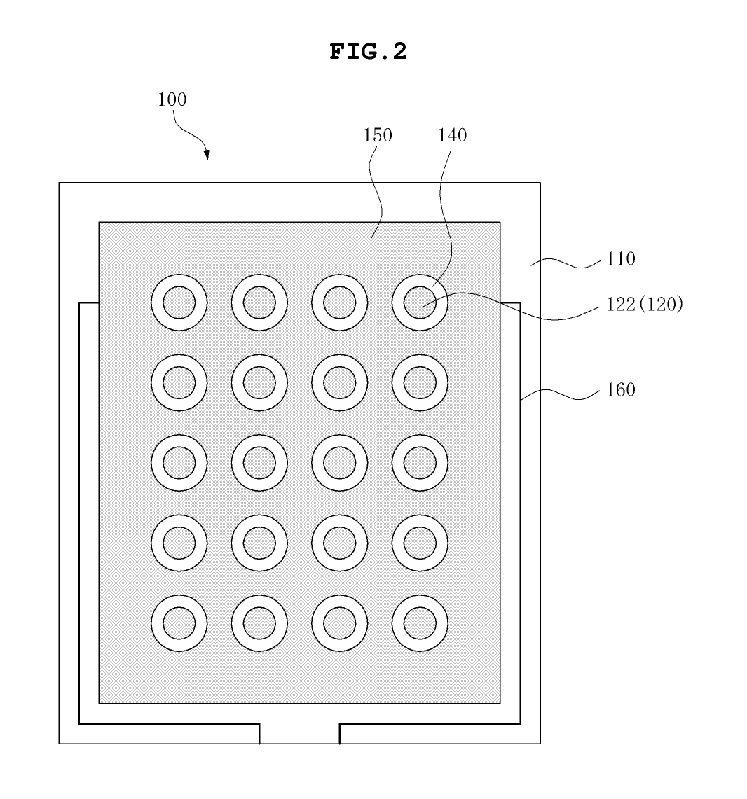

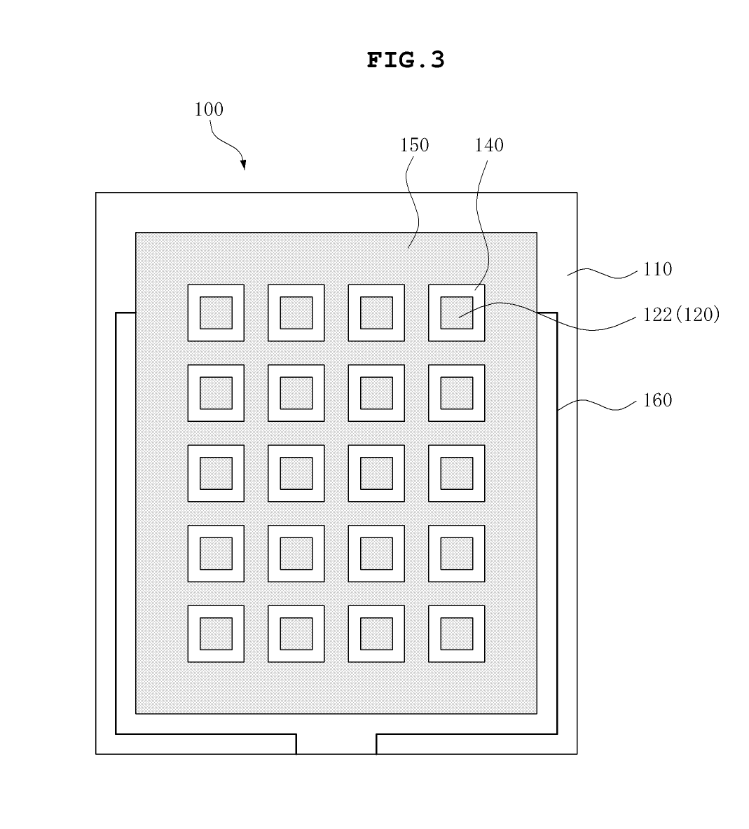

FIG. 2 is a plan view illustrating an example of an electrode pattern in the touch sensor according to the preferred embodiment of the present invention and FIG. 3 is a plan view illustrating another example of the electrode pattern in the touch sensor according to the preferred embodiment of the present invention.

As illustrated in FIGS. 2 and 3, the first electrode 120 having the first insulating layer 140 formed on one surface thereof and the second electrode 150 may have patterns.

First, as illustrated in FIG. 2, the through-hole 141 of the first insulating layer 140 is formed in a circle such that the other portion 122 of the first electrode 120 formed on the other portion of the first insulating layer 140 may have a circular pattern and the second electrode 150 formed on the other portion of the first insulating layer 140 may have a pattern corresponding to the other portion 122 of the first electrode 120 while being spaced apart from an edge of the first electrode 120 at a predetermined distance.

Further, as illustrated in FIG. 3, the through-hole 141 of the first insulating layer 140 is formed in a quadrangle such that the other portion 122 of the first electrode 120 formed on the other portion of the first insulating layer 140 may have a quadrangular pattern and the second electrode 150 formed on the other portion of the first insulating layer 140 may have a pattern corresponding to the other portion 122 of the first electrode 120 while being spaced apart from an edge of the first electrode 120 by a predetermined distance.

However, the patterns of the first electrode 120 and the second electrode 150 of the touch sensor 100 according to the preferred embodiment of the present invention are not limited thereto, and therefore, may be formed in various forms, such as, for example, a quadrangle, a diamond, and the like.

Meanwhile, referring to FIG. 1, the touch sensor 100 according to the preferred embodiment of the present invention may further include electrode wirings that are formed at the edges of the first electrode 120 and the second electrode 150.

The electrode wiring is configured of a first electrode wiring 130 that is formed at the edge of the first electrode 120 and a second electrode wiring 160 that is formed at the edge of the second electrode 150.

Here, the first electrode wiring 130 and the second electrode wiring 160 receive electrical signals from the first electrode 120 and the second electrode 150.

In this case, the first electrode wiring 130 is integrally formed with the first electrode 120 and the second electrode wiring 160 is integrally formed with the second electrode 150, thereby to simplifying the manufacturing process and reducing lead time, but the present invention is not necessarily limited thereto.

Meanwhile, the touch sensor according to the preferred embodiment of the present invention may further include a second insulating layer (not illustrated) that is formed on the other portion 122 of the first electrode 120 and one surface of the first insulating layer 140 including the second electrode 150.

The second insulating layer serves to protect the first electrode 120 and the second electrode 150. Here, the second insulating layer 140 may be formed of epoxy or acrylic based resin, a SiOx thin film, a SiNx thin film, and the like, by printing, chemical vapor deposition (CVD), sputtering, and the like. In this case, the second insulating layer 140 may be formed of, for example, silicon dioxide (SiO₂), but a material of the second insulating layer 140 according to the preferred embodiment of the present invention is not limited thereto.

Meanwhile, the touch sensor 100 according to the preferred embodiment of the present invention may further include a cover film (not illustrated) that is formed on an upper portion of the second electrode wiring 160 and covers the first electrode wiring 130 and the second electrode wiring 160.

Here, the cover film is formed to prevent the first electrode wiring 130 and the second electrode wiring 160 from be recognized from the outside, when the first electrode wiring 130 and the second electrode wiring 160 are formed of metal such as silver paste. The cover film may be formed by printing ink having light brightness such as, for example, black ink, but a material of the cover film of the touch sensor 100 according to the preferred embodiment of the present invention is not limited thereto.

As a result, in the touch sensor 100 according to the preferred embodiment of the present invention configured as described above, one portion 121 of the first electrode 120 is formed over an active region of the transparent substrate 110 other than an inactive region of the transparent to substrate 110 on which the first electrode wiring 130 is formed, thereby easily blocking noise generated from a display unit that is located at a lower portion of the touch sensor 100.

Further, one portion 121 of the first electrode 120 is formed on most of one surface of the transparent substrate 110 and the other portion of the first electrode 120 is extendedly formed in the through-hole 141 of the first insulating layer 140 and around the through-hole 141 of one surface of the first insulating layer 140, such that an area in which the electrode is formed is increased, thereby reducing resistance and improve touch sensitivity.

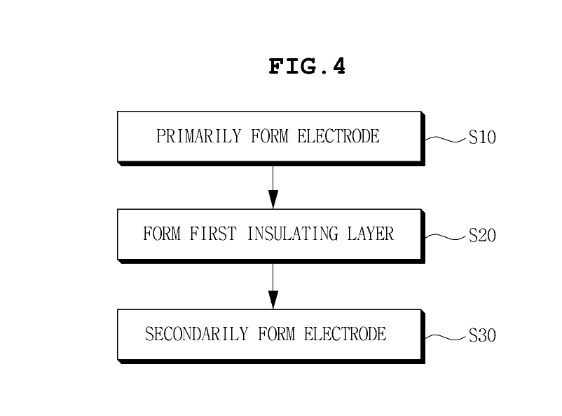

FIG. 4 is a flow chart illustrating a method of manufacturing a touch sensor according to a preferred embodiment of the present invention.

Referring to FIG. 4, a method of manufacturing a touch sensor according to an embodiment of the present invention may include primarily forming an electrode (S10), forming a first insulating layer (S20), and secondarily forming an electrode (S30).

Hereinafter, the method of manufacturing a touch sensor according to the preferred embodiment of the present invention will be described in more detail with reference to FIGS. 4 to 10. Further, the method of manufacturing a touch sensor according to the preferred embodiment of the present invention relates to the method of manufacturing a touch sensor 100 according to the present invention and the same components are denoted by the same reference numerals.

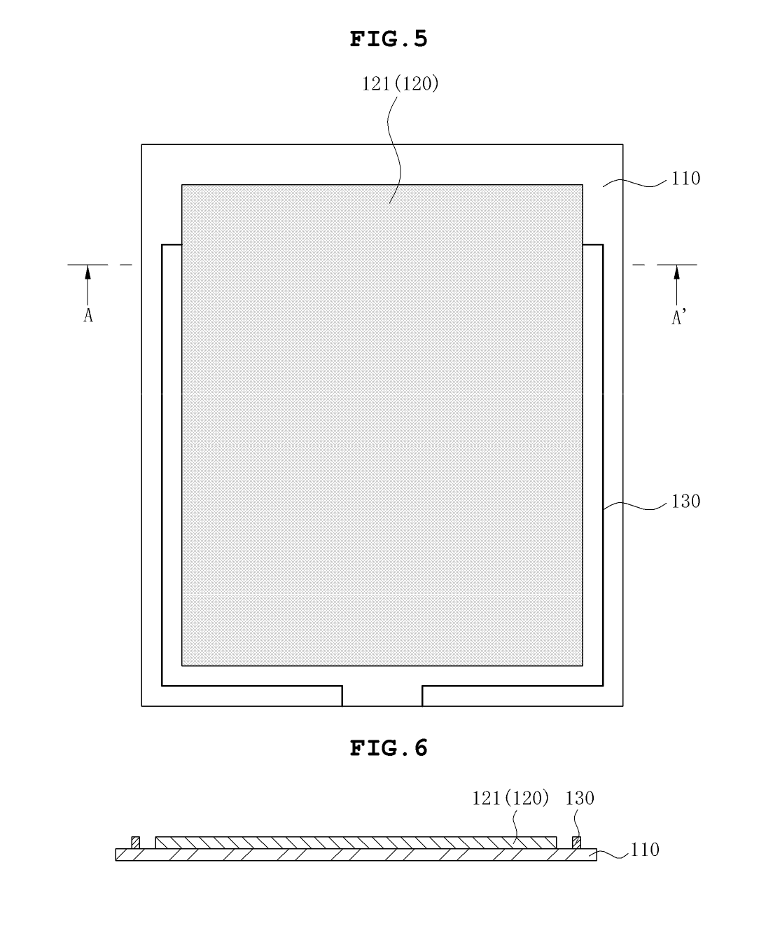

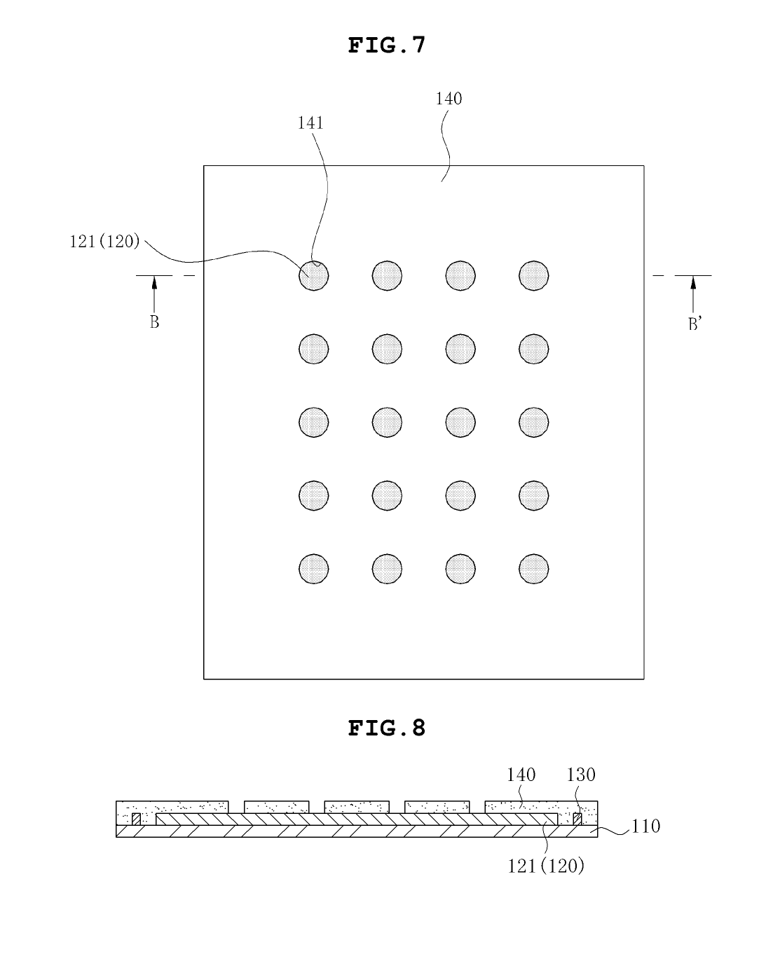

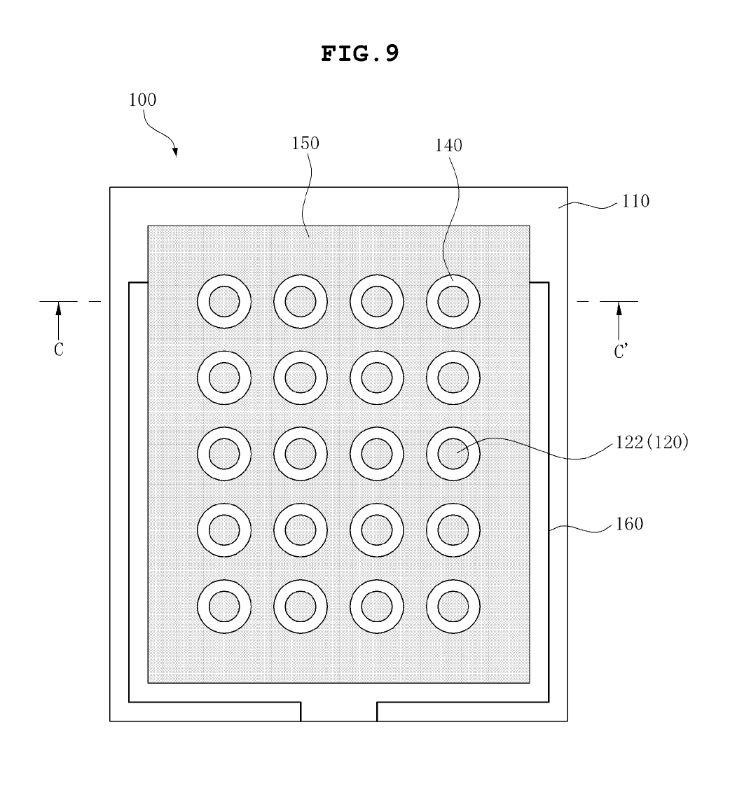

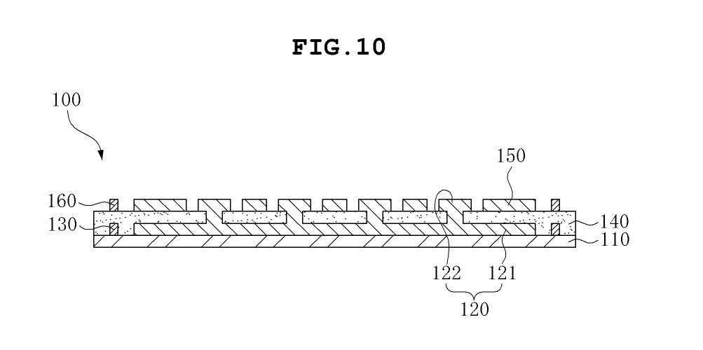

FIGS. 5 to 10 are conceptual diagrams illustrating a method of manufacturing a touch sensor according to the preferred embodiment of the present invention in a process order. Here, FIG. 6 is a cross-sectional view of the line A-A′ of FIG. 5, FIG. 8 is a cross-sectional view of the line B-B′ of FIG. 7, and FIG. 10 is a cross-sectional view of the line C-C′ of FIG. 9.

Referring to FIGS. 4 to 6, in the primarily forming of the electrode (S10), one portion 121 of the first electrode 120 is formed on one surface of the transparent substrate 110.

Here, the transparent substrate 110 provides the substrate part on which the electrode is formed and may be, for example, glass or tempered glass, but a material of the transparent substrate 110 according to the preferred embodiment of the present invention is not necessarily formed of a glass material and therefore, as another example, the transparent substrate 110 may be formed of a film. Here, the transparent substrate 110 may be formed in a rectangular plate shape having a predetermined thickness, but the shape of the transparent substrate 110 according to the preferred embodiment of the present invention is not limited thereto.

In this case, the film may be formed of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), and the like, but are not necessarily limited thereto.

Further, the first electrode 120 may be formed of indium-tin oxide (ITO).

Further, one portion 121 of the first electrode 120 may be formed by a dry process, a wet process, or a direct patterning process. Here, the dry process means sputtering, evaporation, and the like, the wet process means dip coating, spin coating, roll coating, spray coating, and the like, and the direct patterning process means screen printing, gravure printing, inkjet printing, and the like. In this case, one portion 121 of the first electrode 120 may be formed by, for example, depositing ITO on the transparent substrate 110, but the method of forming one portion 121 of the first electrode 120 according to the preferred embodiment of the present invention is not limited thereto.

Further, one portion 121 of the first electrode 120 may be formed over one surface of the transparent substrate 110 other than an edge of one surface of the transparent substrate 110.

Meanwhile, the method of manufacturing a touch sensor according to the preferred embodiment of the present invention may further include forming the first electrode wiring 130 at an edge of one portion 121 of the first electrode 120 after or simultaneously with the primary forming of the electrode (S10). Here, the first electrode wiring 130 is formed at an edge of one surface of the transparent substrate 110 that is an inactive region of the touch sensor 100. In this case, the first electrode wiring 130 receives an electrical signal from the first electrode 120.

Further, the first electrode wiring 130 is integrally formed with the first electrode 120, thereby simplifying the manufacturing process and reducing the lead time, but the present invention is not limited thereto.

Referring to FIGS. 4, 7, and 8, in the forming of the first insulating layer (S20), the first insulating layer 140 is formed on one surface of the first electrode 120. In this case, the first insulating layer 140 is formed so that the plurality of through-holes 141 are formed. Here, the through hole 141 penetrates through both surfaces of the first insulating layer 140 and the flat cross section thereof may have a circle or a quadrangle, but the through-hole 141 shape of the present invention is not necessarily limited thereto.

The first insulating layer 140 protects one portion 121 of the first electrode 120 and serves to provide an area in which the other portion 122 of the first electrode 120 and the second electrode 150 are formed. Here, the first insulating layer 140 may be formed of epoxy or acrylic based resin, a SiOx thin film, a SiNx thin film, and the like, by printing, chemical vapor deposition (CVD), sputtering, and the like. In this case, the first insulating layer 140 may be formed of, for example, silicon dioxide (SiO₂), but a material of the first insulating layer 140 according to the preferred embodiment of the present invention is not limited thereto.

Referring to FIGS. 4, 9, and 10, in the secondarily forming of the electrode (S30), the other portion 122 of the first electrode 120 and the second electrode 150 are formed on one surface of the first insulating layer 140.

Further, the first electrode 120 and the second electrode 150 may be formed of indium-tin oxide (110).

Further, the other portion 122 of the first electrode 120 and the second electrode 150 may be formed by a dry process, a wet process, or a direct patterning process. Here, the dry process means sputtering, evaporation, and the like, the wet process means dip coating, spin coating, roll coating, spray coating, and the like, and the direct patterning process means screen printing, gravure printing, inkjet printing, and the like. In this case, the other portion 121 of the first electrode 120 and the second electrode 150 may be formed by, for example, depositing ITO on the transparent substrate 110, but the method of forming the other portion 122 of the first electrode 120 and the second electrode 150 according to the preferred embodiment of the present invention is not limited thereto. Here, the other portion 122 of the first electrode 120 is formed by depositing ITO in the through-hole 141 of the first insulating layer 140 and around or along the through-hole 141 on one surface of the first insulating layer 140. Therefore, the other portion 122 of the first electrode 120 may be extendedly formed through one portion 121 and the through hole 141.

Further, when depositing ITO on one surface of the first insulating layer 140, the second electrode 150 may be formed by depositing ITO so as to be spaced apart from the other portion 122 of 120 at a predetermined distance.

Meanwhile, as illustrated in FIGS. 2 and 3, in the secondarily forming of the electrode (S30), the pattern may be formed at the time of forming the first electrode 120 and the second electrode 150 on one surface of the first insulating layer 140.

First, as illustrated in FIG. 2, the through-hole 141 of the first insulating layer 140 is formed in a circle such that the other portion 122 of the first electrode 120 formed on the other portion of the first insulating layer 140 may have a circular pattern and the second electrode 150 formed on the other portion of the first insulating layer 140 may have a pattern corresponding to the other portion 122 of the first electrode 120 while being spaced apart from an edge of the first electrode 120 at a predetermined distance.

Further, as illustrated in FIG. 3, the through-hole 141 of the first insulating layer 140 is formed in a quadrangle such that the other portion 122 of the first electrode 120 formed on the other portion of the first insulating layer 140 may have a quadrangular pattern and the second electrode 150 formed on the other portion of the first insulating layer 140 may have a pattern corresponding to the other portion 122 of the first electrode 120 while being spaced apart from an edge of the first electrode 120 at a predetermined distance.

However, in the method of manufacturing a touch sensor according to the preferred embodiment of the present invention, the patterns of the first electrode 120 and the second electrode 150 are not limited thereto, and therefore, may be formed in various forms, such as, for example, a quadrangle, a diamond, and the like.

Meanwhile, the method of manufacturing a touch sensor according to the preferred embodiment of the present invention may further include forming the second electrode wiring 160 at the edge of the second electrode 150 after or simultaneously with the secondarily forming of the electrode (S30). Here, the second electrode wiring 160 is formed at the edge of one surface of the first insulating layer 140 that is the inactive region of the touch sensor 100. In this case, the second electrode wiring 160 receives an electrical signal from the second electrode 150.

Further, the second electrode wiring 160 is integrally formed with the second electrode 150, thereby simplifying the manufacturing process and reducing the lead time, but the present invention is not limited thereto.

Meanwhile, the method of manufacturing a touch sensor according to the preferred embodiment of the present invention may further include forming the second insulating layer that is formed on the other portion 122 of the first electrode 120 and one surface of the first insulating layer 140 including the second electrode 150 after the secondarily forming of the electrode (S30).

The second insulating layer serves to protect the first electrode 120 and the second electrode 150. Here, the second insulating layer 140 may be formed of epoxy or acrylic based resin, a SiOx thin film, a SiNx thin film, and the like, by printing, chemical vapor deposition (CVD), sputtering, and the like. In this case, the second insulating layer 140 may be formed of, for example, silicon dioxide (SiO₂), but a material of the second insulating layer 140 according to the preferred embodiment of the present invention is not limited thereto.

Meanwhile, the method of manufacturing a touch sensor according to the preferred embodiment of the present invention may further include forming the cover film that covers the first electrode wiring 130 and the second electrode wiring 160 by forming the cover film on the upper portion of the second electrode wiring 160 after the forming of the second electrode wiring 160 or the forming of the second insulating layer.

Here, the cover film is to prevent the first electrode wiring 130 and the second electrode wiring 160 from be recognized from the outside, when the first electrode wiring 130 and the second electrode wiring 160 are formed of metal such as silver paste. The cover film may be formed by printing ink having light brightness such as, for example, black ink, but a material of the cover film of the method of manufacturing a touch sensor according to the preferred embodiment of the present invention is not limited thereto.

As a result, in the method of manufacturing a touch sensor according to the preferred embodiment of the present invention configured as described above, one portion 121 of the first electrode is formed over the active region of the transparent substrate 110 other than the inactive region of the transparent substrate 110 on which the first electrode wiring 130 is formed, thereby easily blocking noise generated from the display unit (not illustrated) that is located at the lower portion of the touch sensor 100.

Further, one portion 121 of the first electrode 120 is formed on most of one surface of the transparent substrate 110 and the other portion of the first electrode 120 is extendedly formed at the through-hole 141 of the first insulating layer 140 and around the through-hole 141 of one surface of the first insulating layer 140, such that an area in which the electrode is formed is increased, thereby reducing resistance and improve touch sensitivity.

According to the preferred embodiments of the present invention, it is possible to extend the area of the electrode and reduce the resistance of the electrode, thereby providing the touch sensor with the remarkably improved touch sensitivity and the method of manufacturing the same.

Further, according to the preferred embodiments of the present invention, it is possible to widely form the lower portion of any one of the plurality of electrodes on one surface of the substrate, thereby easily blocking the noise generated from the display.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch sensor, comprising:
a transparent substrate;
a first electrode formed on one surface of the transparent substrate;
a first insulating layer formed on one surface of the first electrode and formed with a through-hole; and
a second electrode formed on one surface of the first insulating layer,
wherein the first electrode is extendedly formed to one surface of the first insulating layer through the through-hole.

2. The touch sensor as set forth in claim 1, wherein the transparent substrate is formed of a film or glass.

3. The touch sensor as set forth in claim 1, wherein the first insulating layer is formed of silicon dioxide (SiO₂).

4. The touch sensor as set forth in claim 1, wherein the first electrode and the second electrode are formed of indium tin oxide (ITO).

5. The touch sensor as set forth in claim 1, wherein the first electrode has a pattern formed on one surface of the first insulating layer, and
the second electrode has a pattern formed on one surface of the first insulating layer and corresponding to the pattern of the first electrode.

6. The touch sensor as set forth in claim 5, wherein the first electrode has a plurality of circular or quadrangular patterns formed on one surface of the first insulating layer, and
the second electrode has patterns formed on one surface of the first insulating layer and corresponding to the patterns of the first electrode while being spaced apart from an edge of the first electrode at a predetermined distance.

7. The touch sensor as set forth in claim 1, further comprising:
a first electrode wiring and a second electrode wiring each formed at edges of the first electrode and the second electrode.

8. A method of manufacturing a touch sensor, comprising:
primarily forming a first electrode on one surface of a transparent substrate;
forming a first insulating layer formed with a through-hole and formed on one surface of the first electrode; and
secondarily forming a second electrode and the first electrode extending through the through-hole on one surface of the first insulating layer.

9. The method as set forth in claim 8, wherein the transparent substrate is formed of a film or glass.

10. The method as set forth in claim 8, wherein in the forming of the first insulating layer, the first insulating layer is formed of a silicon dioxide (SiO₂) material.

11. The method as set forth in claim 8, further comprising:
after the primarily forming of the electrode, forming a first electrode wiring at an edge of the first electrode.

12. The method as set forth in claim 8, further comprising:
after the secondarily forming of the electrode, forming a second electrode wiring at an edge of the second electrode.

13. The method as set forth in claim 8, wherein the first electrode and the second electrode are formed of indium tin oxide (ITO).

14. The method as set forth in claim 8, wherein in the primarily forming of the electrode and the secondarily forming of the electrode, the first electrode and the second electrode are formed by deposition.

15. The method as set forth in claim 8, wherein in the secondarily forming of the electrode,
the first electrode has a pattern formed on one surface of the first insulating layer, and
the second electrode has a pattern corresponding to the pattern of the first electrode.

16. The method as set forth in claim 15, wherein in the secondarily forming of the electrode,
the first electrode has a plurality of circular or quadrangular patterns formed on one surface of the first insulating layer, and
the second electrode has patterns formed on one surface of the first insulating layer and corresponding to the patterns of the first electrode while being spaced apart from an edge of the first electrode at a predetermined distance.
